(19) United States
(12) Patent Application Publication
(10) Pub. No.: US 2015/0096613 A1
(43) Pub. Date: Apr. 9, 2015

(54) PHOTOVOLTAIC DEVICE AND METHOD OF MANUFACTURING THE SAME

(71) Applicant: SINO-AMERICAN SILICON PRODUCTS INC., HSINCHU (TW)

(72) Inventors: BUDI TJAHJONO, YILAN COUNTY (TW); MING-JUI YANG, YILAN COUNTY (TW); CHUAN-WEN TING, YILAN COUNTY (TW); WEN SHENG WU, YILAN COUNTY (TW); KUO-WEI SHEN, YILAN COUNTY (TW); CHIEN HONG LIU, TAOYUAN COUNTY (TW)

(21) Appl. No.: 14/568,328

(22) Filed: Dec. 12, 2014

Related U.S. Application Data
(63) Continuation-in-part of application No. 13/924,752, filed on Jun. 24, 2013.

(30) Foreign Application Priority Data
Dec. 19, 2013 (TW) 102147056

(51) Int. Cl. H01L 31/0203; H01L 31/0236; H01L 31/02; H01L 31/0216

(52) U.S. Cl. CPC H01L 31/0203; H01L 31/02168; H01L 31/02366; H01L 31/0201
USPC 136/256; 438/65

(57) ABSTRACT

The invention provides a photovoltaic device and method of manufacturing the same. The photovoltaic device of the invention includes a semiconductor structure assembly and a protection layer. The semiconductor structure assembly has a plurality of side surfaces, and includes a p-n junction, an n-p junction, a p-i-n junction, an n-i-p junction, a tandem junction or a multi-junction. In particular, the protection layer is formed to overlay the sides of the semiconductor structure assembly. Thereby, the protection layer can effectively inhibit the potential-induced degradation effect of the photovoltaic device of the invention.

### CROSS REFERENCE TO RELATED APPLICATIONS

This Application is a Continuation-in-Part of application Ser. No. 13/924,752, filed Jun. 24, 2013, now pending, and entitled SOLAR CELL AND METHOD OF MANUFACTURING THE SAME.

### BACKGROUND OF THE INSTANT DISCLOSURE

1. Field of the Invention

The instant disclosure relates to a photovoltaic device and method of manufacturing the same; in particular, to the photovoltaic device effectively inhibiting potential-induced degradation (PID) effect and method of manufacturing the same.

2. Description of Related Art

Emphasis on reliability problems of photovoltaic devices and package module thereof resulted from PID effect are becoming more evident. Manufacturers devote themselves into development of photovoltaic devices and package module thereof capable of inhibiting PID. PID effect was first discovered from n-type silicon substrate based photovoltaic devices by the Sunpower company in 2005. That package module is conditioned under long-term high temperature, humid surroundings, and high voltage that lead to current leakage between the glass material and the package module. The surface effect of the photovoltaic devices is exacerbated by the enormous amount of electrical charge gathering on the surface of the photovoltaic device.

Consequently, the efficiency of the photovoltaic device, such as fill factor (FF), short circuit current density (J_{sc}), and Open-circuit voltage (V_{oc}) etc., are rapidly and massively decreased under original standard of design. All the phenomenon inducing decay as mentioned above are PID effects.

Regarding to photovoltaic devices made of n-type silicon substrate, prior arts provides methods to inhibit PID effects such as adjusting refractive index of the anti-reflection layer (SiNₓ). By adjusting refractive index, however, the contribution of the anti-reflection layer is also sacrificed, which means that reflection index of the anti-reflection layer is raised. Besides, the above-mentioned method is not compatible with other types of photovoltaic devices.

Research articles with such issues have indicated that the PID effect results from the following three mechanisms: the abnormal influence on the active region of the surface of the semiconductor material; performance attenuation and bypass phenomenon of junction of the semiconductor; electrolytic corrosion and migrating of the electrically-conductive metal ion. Generally speaking, PID effect mostly initiates at edges of photovoltaic devices. Hence, the prevention of PID effect from the photovoltaic device, especially PID effect originated from edges of photovoltaic devices in order to prolong life-span, is an important issue for those skilled in the art to solve.

### SUMMARY OF THE INVENTION

The object of the instant disclosure is to provide a photovoltaic device that effectively inhibits the PID effect and method of manufacturing the same.

One of the preferred embodiments of the instant disclosure provides a photovoltaic device comprising: a semiconductor structure assembly having a plurality of side surfaces, and including a junction being a p-n junction, n-p junction, p-i-n junction, n-i-p junction, double junction, or a multiple junction; and a first protection layer formed to overlay the side surfaces of the semiconductor structure assembly, so as to inhibit occurrence of potential-induced degradation effect within covering the photovoltaic device.

Furthermore, the photovoltaic device of the instant disclosure also comprises a second protection layer. The second protection layer is formed to overlay the first protection layer.

One of the preferred embodiments of the instant disclosure provides a method of manufacturing the photovoltaic device, comprising the following steps: preparing a semiconductor structure assembly, wherein the semiconductor structure assembly has a plurality of side surfaces, and includes a junction being a p-n junction, n-p junction, p-i-n junction, n-i-p junction, double junction, or a multiple junction; and forming a first protection layer to overlay the side surfaces.

The difference between the instant disclosure and the prior art is that the first protection layer overlaying the plurality of the side surfaces are capable of inhibiting occurrence of PID effect on the photovoltaic device in the instant disclosure.

Advantages and essence of the instant disclosure can be further understood by the following detailed description provided along with illustrations to facilitate the disclosure of the present invention without limiting the same.

### BRIEF DESCRIPTION OF THE DRAWINGS

FIG. 1 shows a cross-sectional view of the photovoltaic device from one preferred embodiment in the instant disclosure.

FIGS. 2-3 show cross-sectional views of the photovoltaic devices according to process of manufacturing the same from one preferred embodiment in the instant disclosure.

FIGS. 4-7 show cross-sectional views of the photovoltaic devices according to process of manufacturing the same from the first example in the instant disclosure.

FIGS. 8-9 show cross-sectional views of the photovoltaic devices according to process of manufacturing the same from the second example in the instant disclosure.

FIGS. 10-11 show cross-sectional views of the photovoltaic devices according to process of manufacturing the same from the third example in the instant disclosure.

FIGS. 12-13 show cross-sectional views of the photovoltaic devices according to process of manufacturing the same from the fourth example in the instant disclosure.

### DETAILED DESCRIPTION OF THE PREFERRED EMBODIMENTS

Please refer to FIG. 1 as a cross-sectional view of the photovoltaic device 1 from one preferred embodiment in the instant disclosure.

As FIG. 1 shows, the instant disclosure provides the photovoltaic device 1 including a semiconductor structure assembly 10 and a first protection layer 12. The semiconductor structure assembly 10 has a plurality of side surfaces 102 that include p-n junction, n-p junction, p-i-n junction, n-i-p junction, double junction, and multiple junction, or junctions of other types. In other words, the photovoltaic device 1 can be a monolithic silicon photovoltaic device, a monolithic silicon liked photovoltaic device, a poly-silicon photovoltaic device, a gallium arsenide photovoltaic device, an amorphous silicon thin film photovoltaic device, a □-silicon thin film photovoltaic device, a Cadmium sulfide (CdS) photovoltaic device, a Cadmium telluride (CdTe) thin film photovoltaic device, CuInSe₂ (CIS) thin film photovoltaic device, Cu(In, Ga)Se₂ (CIGS) thin film photovoltaic device, or a dye-sensitized thin film photovoltaic device (also called dye-sensitized solar cell, DSSC) etc. In FIG. 1, junction 104 shown in the semiconductor structure assembly 10 can be a representative of this embodiment.

In particular, the first protection layer 12 is formed to overlay the side surface 102, and the side face 102 can be more than one in quantity, thereby the first protection layer 12 is able to effectively prohibit the photovoltaic device 1 from occurring PID effect.

In one embodiment, chemical composition of the first protection layer 12 can include Aluminum oxide (Al₂O₃), Titanic oxide (TiO₂), Zirconium oxide (ZrO₂), Hafnium oxide (HfO₂), or any combination of at least two of the above compounds.

In one embodiment, thickness of the first protection layer 12 ranges from 0.2 to 100 nanometer (nm).

Furthermore, FIG. 1 shows that the photovoltaic device 1 also includes a second protection layer 14. The second protection layer 14 is formed to overlay the first protection layer 12.

In one embodiment, chemical composition of the second protection layer 14 can include Silicon nitride (Si₃N₄), Silicon oxynitride (SiON), or mixtures of the two compounds above.

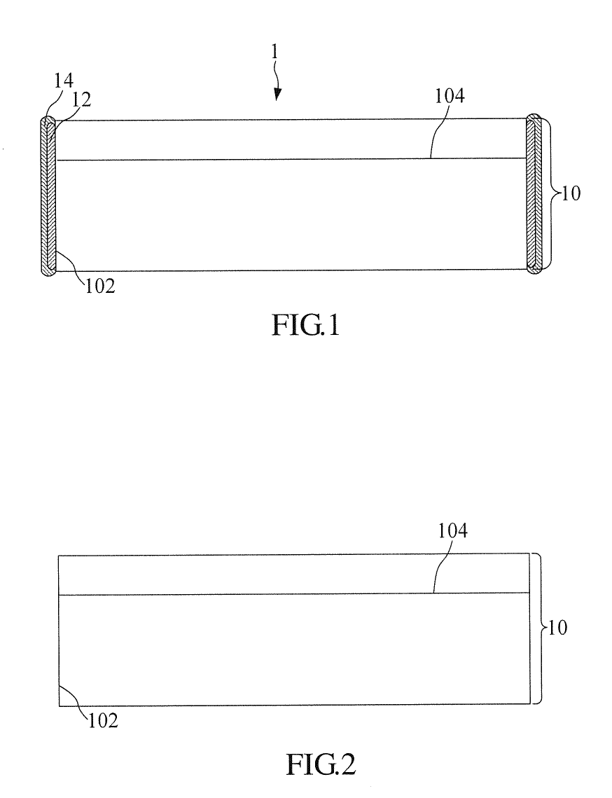

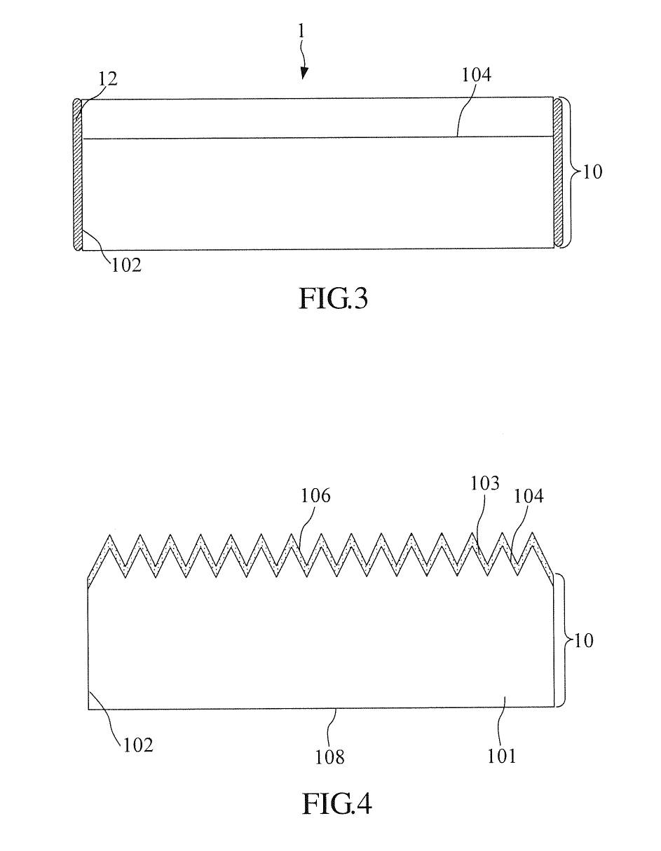

Please refer to FIGS. 2-3, which show cross-sectional views of the photovoltaic device 1 of the process of manufacturing the same in accordance with a preferred embodiment of the instant disclosure.

As FIG. 2 shows, firstly, the method of the instant disclosure relates to the preparation of the semiconductor structure assembly 10, in which the semiconductor structure assembly 10 has a plurality of side surfaces 102 which can include p-n junction, n-p junction, p-i-n junction, n-i-p junction, double junction, multiple junction, or junctions of other types. In FIG. 2, junction 104 shown in the semiconductor structure assembly 10 can be a representative of this embodiment.

As FIG. 3 shows, the method of the instant disclosure relates to the formation of a first protection layer 12 to overlay the side surface 102, and the side surface 102 can be more than one in quantity, of the semiconductor structure assembly 10.

Furthermore, the method of the instant disclosure is related to forming a second protection layer 14 to overlay the first protection layer 12 so that the structure of the photovoltaic device as shown in FIG. 1 shows is accomplished.

The following paragraphs will represent several examples in detail to demonstrate the photovoltaic device 1 and the manufacturing method implemented to form the structure of silicon substrate based on the photovoltaic device.

Please refer to FIGS. 4-7, which show cross-sectional views of the structure of the photovoltaic device according to process of manufacturing the same from a first example in the instant disclosure.

As FIG. 4 shows, firstly, the method of the instant disclosure relates to the preparation of the semiconductor structure assembly 10, in which the semiconductor structure assembly 10 has a plurality of side surfaces 102, a front surface 106, and a rear surface 108 arranged opposite to the front surface 106. The semiconductor structure assembly 10 with a junction 104 as shown in FIG. 4 can be a representative of this example. When being prepared, the semiconductor structure assembly 10 can include a silicon substrate 101 in a first conductive configuration, and the silicon substrate 101 can be made of monolithic silicon substrate, monolithic silicon liked substrate, or poly-silicon substrate etc. Thickness of the silicon substrate 101 ranges from about 150 □m to 220 □m, but is not limited thereto.

The semiconductor structure assembly 10 can also include the junction 104, however, the possible types for forming the junction 104 have been introduced in the preceding paragraphs, and needn't be repeated again here.

Referring to FIG. 4, the method of the instant disclosure relates to the texturing of the front surface 106 which means that the front surface 106 is a textured surface. The texturing of the front surface 106 can be achieved by etching with acid solution or base solution so that, for example, pyramid texturing structures of non-uniform sizes are formed thereon. The front surface 106 functions as a light incident face. The textured front surface 106 can effectively reduce reflection index of incident light.

Typical surface texturing technology is often used for making V-type groove or pyramid texturing structure that exhibits roughness from sub-millimeter to micrometer scale. With the continuous demand for high photoelectric conversion efficiency, techniques that enhance the roughness of the incident face to the scale of nanometer have been developed. The incident face of these photovoltaic devices presents a distribution of nano-column structures thereon that exhibit a relatively high depth-width ratio (about 1 □m in depth and 100 nm in width). Photovoltaic devices having the incident face textured in nanometer scale help to lower the reflection index of the incident light, which has a wavelength of 300 nm to 1000 nm, less than 5% of reflectance.

In the first example, the method of the instant disclosure further relates to the incorporation of a doping agent under a predetermined range into the textured front surface 106 in order to form a semiconductor region 103 with a second conductive configuration functioning as an emitter of the silicon substrate based photovoltaic device. The doping agent can be boron (B), phosphorus (P) or Arsenic (As) etc. Furnace diffusion, screen printing, spin coating or spray coating could be adopted to carry out the adding of the doping agents.

In one embodiment, the silicon substrate 101 can be of p- type and the semiconductor region 103 can be of n-type, while in another embodiment, the silicon substrate 101 can be of n-type and the semiconductor region 103 can be of p-type.

Furthermore, as FIG. 5 shows, the first example of the instant disclosure relates to the formation of a first protection layer 12 to overlay the plurality of the side surfaces 102 of the semiconductor structure assembly 10. In addition, the first protection layer 12 further extends to an edge of the front surface 106 as well as to an edge of the rear surface 10.

In one embodiment, as the first protection layer 12 extends from the side surface 102 to the edge of the front surface 106, a part of the first protection layer 12 covering the edge of the front surface 106 exhibits a width between 0.1 mm to 100 mm, and as the first protection layer 12 extends from the side surface 102 to the edge of the rear surface 108, a part of the first protection layer 12 covering the edge of the rear surface 108 exhibits a width between 0.1 mm to 100 mm, but is not limited thereto. The thickness range and the composition of the first protection layer 12 have been introduced in the preceding paragraphs, and needn't be repeated here.

In one embodiment, formation of the first protection layer 12 can be done by adopting any one of the following procedures: plasma-enhanced chemical vapor deposition (PECVD), atmospheric pressure chemical vapor deposition (APCVD), metal-organic chemical vapor deposition (MOCVD), atomic layer deposition (ALD), or physical vapor deposition (PVD).

Moreover, as FIG. 5 also shows, to prevent the first protection layer 12 from being polluted by the metal elements from electrodes formed subsequently, the method of the instant disclosure relates to the formation of a second protection layer 14 to overlay the first protection layer 12. The composition of the second protection layer 14 has been introduced in the preceding paragraphs, and needn't be repeated here.

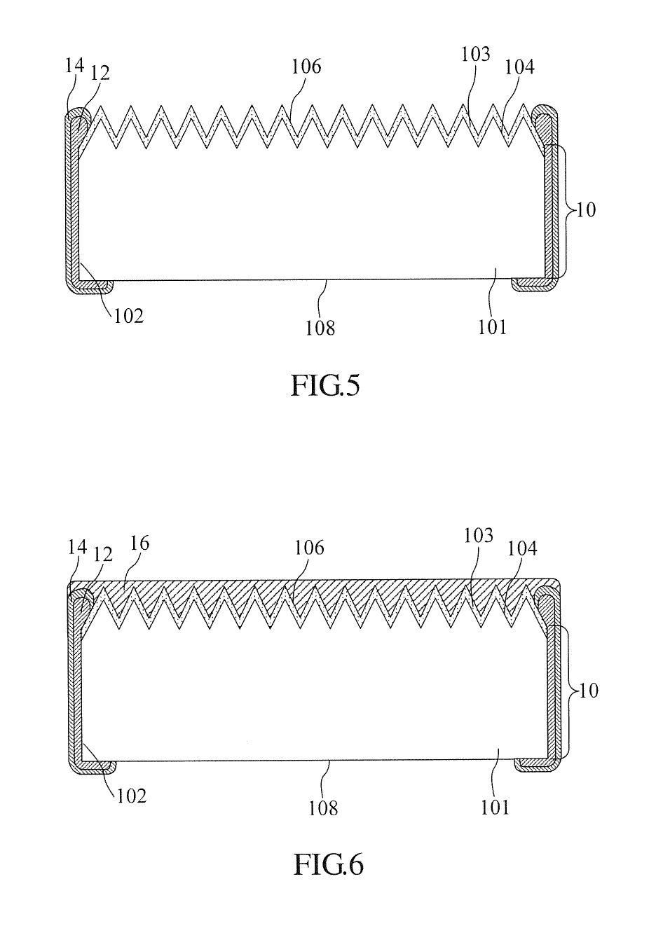

As FIG. 6 shows, moreover, the first example of the method of the instant disclosure relates to the formation of an anti-reflection layer 16 on the front surface 106 and the extension to overlay an edge of the first protection layer 12. In one embodiment, the anti-reflection layer 16 can be formed by adopting CVD or PCD etc. Besides, the anti-reflection layer 16 not only helps to lower complex velocity of surface carrier of the silicon substrate photovoltaic device 1, but also helps arise photoelectric current produced and protect the silicon substrate based photovoltaic device 10 from scraping or moisture for example.

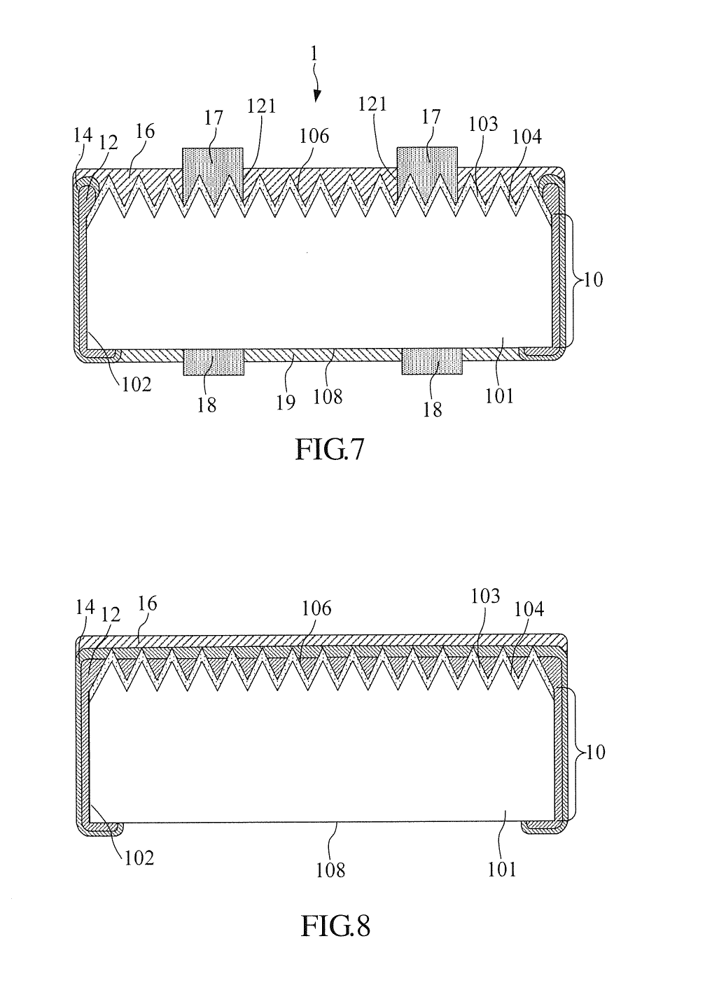

As FIG. 7 shows, subsequently, the first example of the method of the instant disclosure relates to the formation of a positive electrode 17 on the anti-reflection layer 16 to forms an ohmic contact with the front surface 106. In one embodiment, the positive electrode 17 can be formed on the front surface 106 by means of partial screen printing or coating with desired metal slurry, for example, argentum (Ag) slurry, and then accomplished by sintering. During sintering, glass powder mixed in the Ag slurry would pass through the anti-reflection layer 16 and form a contact with silicon in the front surface 106, allowing the positive electrode 17 to form an ohmic contact with the front surface 106. In another embodiment, the first example of the method of the instant disclosure also relates to the formation of an opening 121 on the anti-reflection layer 16 to expose the front surface 106 under the anti-reflection layer 16; and forming a positive electrode 17 inside the opening 121 to overlay the exposed front surface 106.

As FIG. 7 shows, the method of the instant disclosure relates to the formation of at least one rear bus-bar electrode 18 on the rear surface 108.

As FIG. 7 also shows, the method of the instant disclosure relates to the formation of a rear electrode 19 on the rear surface 108 to overlay a region on the rear surface 108 without covering the at least one rear bus-bar electrode 18, so that the silicon substrate based photovoltaic device 1 is accomplished. In one embodiment, the positive electrode 17, the at least one rear bus-bar electrode 18 and the rear electrode 19 can be formed by partial screen printing or coating with desired metal slurry on the anti-reflection layer 16 and the rear surface 18, and is finished off by co-firing process (sintering) at 570 to 840 degrees Celsius. Subsequently, the photovoltaic device 1 will undergo a package process to form a package module. When module is in use, the overlaying of the first protection layer 12 on the plurality of side surfaces 102 of the semiconductor 12 allows the electrical charges to accumulate on the packaging material, which are usually ethylene-vinyl acetate (EVA) or glass substrate, to be directed towards the silicon substrate in the first conductive configuration. Hence, the first protection layer 12 can effectively prevent the PID effect, particularly the PID effect initiated from the side surface 102 of the silicon substrate based photovoltaic device 1, on the photovoltaic device 1.

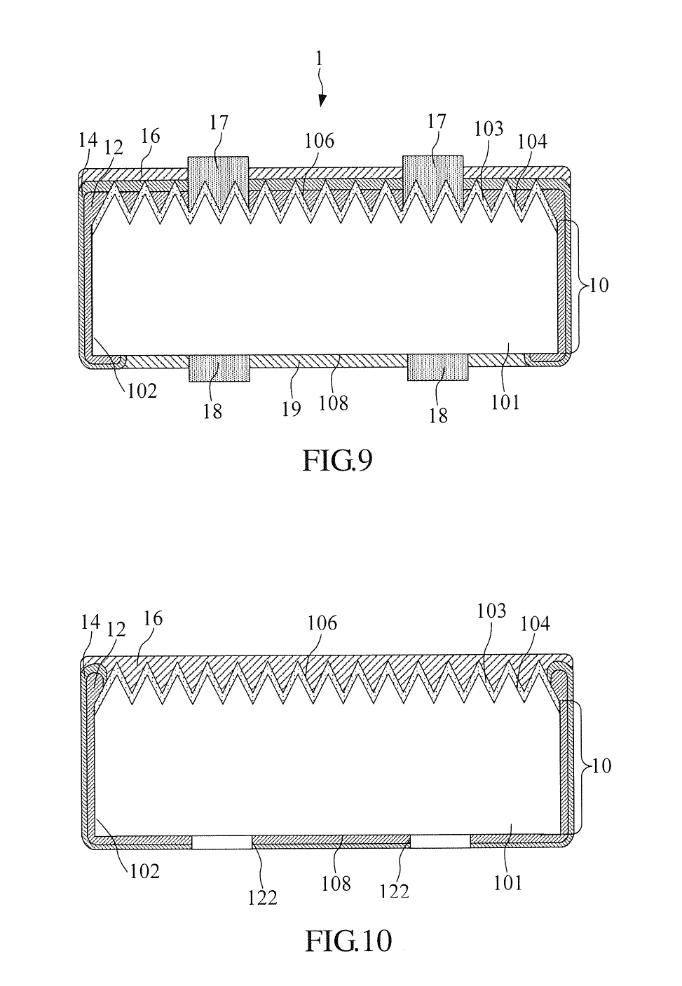

Please refer to FIGS. 8-9, which show cross-sectional views of the photovoltaic device structures according to process for manufacturing the same from the second example in the instant disclosure.

The second example is overall similar to the first example. Hence, the following description will merely show the differences between the second example and the first example. As FIG. 8 shows, the second example of the method relates to the extension of the first protection layer 12 to overlay the front surface 106, and the extension of the first protection layer 12 to an edge of the rear surface 108.

As FIG. 8 shows, the second example of the method relates to the formation of an anti-reflection layer 16 to overlay the first protection layer 12 on the front surface 106. The FIG. 8 also shows that a second protection 14 is formed to overlay the first protection layer 12.

As FIG. 9 shows, finally, the second example of the method of the instant disclosure relates to the formation of a positive 17 on the anti-reflection layer 16, and having the positive electrode 17 form an ohmic contact with the front surface 106. The method also relates to the formation of at least one rear bus-bar electrode 18 on the rear surface 108, and the formation of a rear electrode 19 on a region of the rear surface 108 without covering the at least one rear bus-bar electrode 18, so as to accomplish the silicon substrate based photovoltaic device 1. In one embodiment, the second example of the method can be used for sintering, the Ag slurry in glass powder passes through the anti-reflection layer 16 to make contact with the silicon of the front surface 106, so as to allow the positive electrode 17 form an ohmic contact with the front surface 106. In another embodiment, the second example of the method relates to the formation of an opening (label not shown) on the anti-reflection layer 16 passing through the first protection layer 16, exposing the front surface 106, and then forming a positive electrode 17 in the opening (label not shown) to overlay the previously exposed front surface 106.

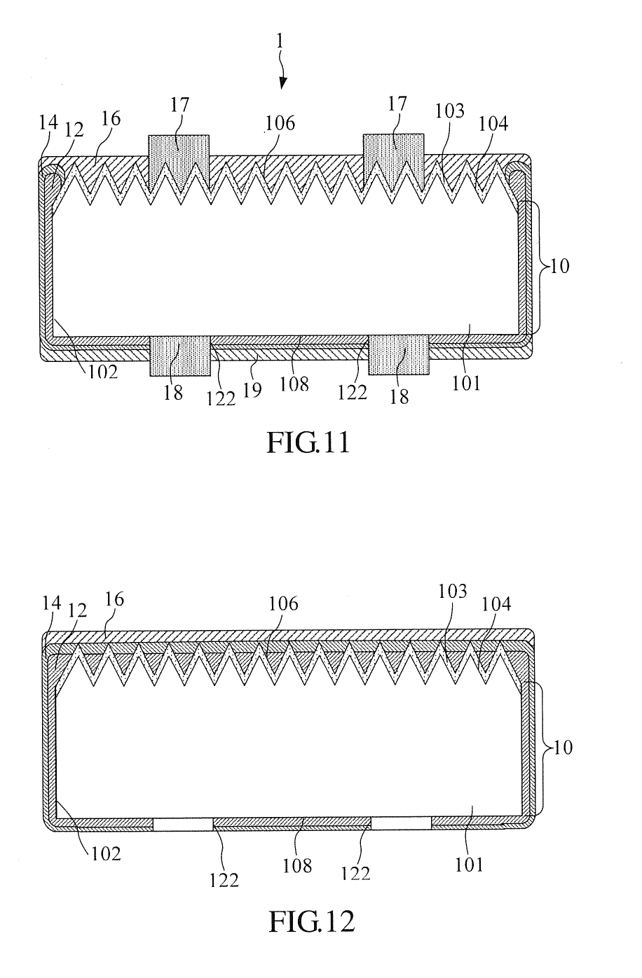

Please refer to FIGS. 10-11, which show cross-sectional views of the silicon substrate based photovoltaic device structure according to process for manufacturing the same from a third embodiment in the instant disclosure.

The third example of the method in the instant disclosure is overall similar to the first example of the method, therefore, the following description will merely show the differences between the third example and the first example. As FIG. 10 shows, the third example of the method relates to the extension of the first protection layer 12 to an edge of the front surface 106, and extension of the first protection layer 12 to overlay the rear surface 108.

As FIG. 10 also shows, the third example of the method in the instant disclosure relates to the formation of an anti-reflection layer 16 on the front surface 106, and extension of the layer 16 to overlay the first protection layer 12 at the edge of the front surface 106. As FIG. 10 also shows, a second protection layer 14 is formed to overlay the first protection layer 12.

Next, the third example of the method relates to the formation of at least a rear bus-bar electrode 18 on the first protection layer 12 and the at least one rear bus-bar electrode 18 form an ohmic contact with the rear electrode. For instance, as FIG. 10 shows, the third example of the method relates to the formation of at least one opening 122 on the protection layer 12 and overlaying on the rear surface 108, wherein the rear surface 108 is exposed from the interior of the at least one opening 122. Next, as FIG. 11 shows, the third example of the method also relates to the formation of at least one rear bus-bar electrode 18 inside the at least one opening 122 to overlay the previously exposed rear surface 108. The third example of the method can also relate to the use of glass powder mixed in the Ag slurry, the Ag slurry passes through the first protection layer 12 to form a contact with silicon of the rear surface 108 during sintering without the need to first form the opening 122, so that the at least one rear bus-bar electrode 18 can form an ohmic contact with the rear surface 108.

As FIG. 11 shows, finally, the third example of the method relates to the formation of a positive electrode 17 on the anti-reflection layer 16 to form an ohmic contact with the front surface 106. The third example of the method also relates to form at least one rear bus-bar electrode 18 and forming a rear electrode 19 to overlay the first protection layer 12 covering the rear surface 108 and to leave the at least one rear bus-bar electrode 18 exposed so that the silicon substrate based photovoltaic device 1 is accomplished. In one embodiment, the third example of the method also relates to the use of glass powder mixed in the Ag slurry, the Ag slurry passes through the anti-reflection layer 16 and the first protection layer 12 to form a contact with silicon of the front surface 106 during sintering, so that the positive electrode 17 can form an ohmic contact with the front surface 106. In another embodiment, the third example of the method also relates to the formation of opening (label not shown) on the anti-reflection layer 16 passing through the first protection layer 12 so that the front surface 106 is exposed, and forming a positive electrode 17 inside the opening to overlay the previously exposed front surface 106.

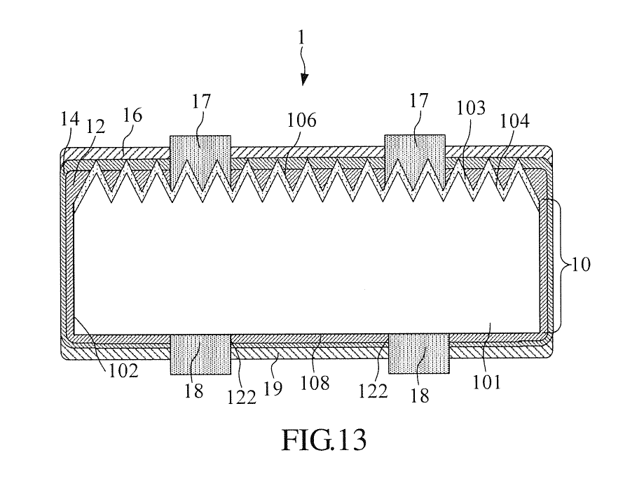

Please refer to FIGS. 12 to 13, which respectively show cross-sectional views of the photovoltaic device according to process of manufacturing the same from the fourth example in the instant disclosure.

The fourth example of the method of the instant disclosure is overall similar to the first example, therefore, the following description will merely introduce the differences between the fourth example and the first example. As FIG. 12 shows, the fourth example of the method relates to the extension of the first protection layer 12 to overlay the front surface 106, and extending the first protection layer 12 to overlay the rear surface 108.

As FIG. 12 shows, the fourth example of the method relates to the formation of an anti-reflection layer 16 to overlay first protection layer 12 on the front surface 106. As FIG. 12 shows, a second protection layer 14 is formed to overlay the first protection layer 12.

Next, the fourth example of the method of the instant disclosure relates to the formation of at least one rear bus-bar electrode 18 on the first protection layer 12, and the at least one rear bus-bar electrode 18 forming an ohmic contact with the rear electrode. For instance, as shown in FIG. 12, the fourth example of the method is to form at least one opening 122 on the first protection layer overlaying the rear surface 108, wherein the rear surface 108 is exposed from inside of the at least one opening 122. Next, as FIG. 13 shows, the fourth example of the method is to form at least on rear bus-bar electrode 18 located inside the at least one opening 122 to cover the previously exposed rear surface 108. The fourth example of the method can also relate to the use of glass powder mixed in the Ag slurry, the Ag slurry passes through the first protection layer 12 to form a contact between silicon of the rear surface 108 and the at least one rear bus-bar electrode 18 during sintering without the need to form the opening 122 first, so that the at least one rear bus-bar electrode 18 can form an ohmic contact with the rear surface 108.

As FIG. 13 shows, at last, the fourth example of the method relates to the formation of a positive electrode 17 on the anti-reflection layer 16 to form an ohmic contact with the front surface 106. The fourth example of the method also relates to the formation of at least one rear bus-bar electrode 18 and forming a rear electrode 19 to overlay the first protection layer 12 on the rear surface 108 without covering the at least one rear bus-bar electrode 18, thus, the silicon substrate based photovoltaic device 1 is provided. In one embodiment, the fourth example of the method relates to the formation of an opening (label not shown) on the anti-reflection layer 16 passing through the first protection layer 12, exposing the front surface 106 from the interior of the opening (label not shown), and then forming a positive electrode 17 in the opening (label not shown) to cover the previously exposed front surface 106.

The following are PID effect related testing results of several silicon substrate based photovoltaic devices A, silicon substrate based photovoltaic devices B and silicon substrate based photovoltaic device C. The silicon substrate based photovoltaic devices A are made according to the third example of the method, of which the structure is as shown in FIG. 11. The silicon substrate based photovoltaic devices B are made by the prior art that teaches the adjustment of the refractive index of the anti-reflection layer (SiNₓ) can inhibit the PID effect. The silicon substrate based photovoltaic devices C are common devices that do not inhibit PID effect. The PID effect test method used packages silicon substrate based photovoltaic device into packaged modules, and then the test method is carried out, in which the testing conditions are set under 85 degrees Celsius at a relative humidity (RH) of 85% for 96 hours.

Please refer to table 1, the tested results of the initial photoelectric conversion efficiency, final photoelectric conversion efficiency, attenuation ratio and shunt resistance (Rₛₕᵤₙₜ) of the silicon substrate based photovoltaic devices A, B and C are listed in table 1. The shunt resistance is for defining the electric leakage of the silicon substrate based photovoltaic devices, in which the larger the shunt resistance is measured, the less the electric leakage would be. The results listed in table 1 prove that the silicon substrate based photovoltaic devices A and B both exhibit higher photoelectric conversion efficiency than the silicon substrate based photovoltaic devices. The attenuation of the photoelectric conversion of the silicon substrate based photovoltaic devices C is quite large, and the shunt resistance values are very low. Since photovoltaic devices slightly reduce the inherent function of the anti-reflection layer, the silicon substrate based photovoltaic device B exhibits a relatively lower photoelectric conversion efficiency than the silicon substrate based photovoltaic devices A. Values of the attenuation ratio of the silicon substrate based photovoltaic devices B are higher than those of the silicon substrate based photovoltaic devices A, and values of the shunt resistance of the silicon substrate based photovoltaic devices B are obviously smaller than those of the silicon substrate based photovoltaic devices A. Apparently, the photovoltaic device of the instant disclosure exhibits better PID effect inhibition than that of the prior art. Besides, the photovoltaic device and the method of manufacturing the same can be applied broadly to every kind of photovoltaic device.

TABLE 1

| | initial | final | | |
|---|---|---|---|---|
| | photoelectric | photoelectric | | |
| | conversion | conversion | attenuation | |
| | efficiency | efficiency | ratio | Rₛₕᵤₙₜ(Ω) |
| Silicon | 17.70%±0.31% | 17.48%±0.29% | 1.24% | 491.79 |
| substrate | | | | |
| based | | | | |
| photovoltaic | | | | |
| device A | | | | |
| Silicon | 17.46%±0.19% | 16.98%±0.20% | 2.72% | 135.67 |
| substrate | | | | |
| based | | | | |
| photovoltaic | | | | |
| device B | | | | |
| Silicon | 17.05%±0.35% | 12.82%±4.61% | 25.00% | 8.67 |
| substrate | | | | |
| based | | | | |
| photovoltaic | | | | |
| device C | | | | |

The descriptions illustrated supra set forth simply the preferred embodiments of the present invention; however, the characteristics of the present invention are by no means restricted thereto. All changes, alternations, or modifications conveniently considered by those skilled in the art are deemed to be encompassed within the scope of the present invention delineated by the following claims.

What is claimed is:

1. A photovoltaic device, comprising:
a semiconductor structure assembly having a plurality of side surfaces and including a junction, the junction being a p-n junction, n-p junction, p-i-n junction, n-i-p junction, double junction, or a multiple junction; and
a first protection layer formed to overlay the side surfaces of the semiconductor structure assembly, so as to inhibit occurrence of potential-induced degradation effect within the photovoltaic device.

2. The photovoltaic device according to claim 1, wherein the first protection layer is selected from the group consisting of aluminum oxide, titanic oxide, zirconium oxide, hafnium oxide, and a combination thereof.

3. The photovoltaic device according to claim 2, further comprising a second protection layer formed to overlay the first protection layer.

4. The photovoltaic device according to claim 3, wherein the second protection layer is selected from the group consisting of silicon nitride, silicon oxynitride, and a combination thereof.

5. The photovoltaic device according to claim 2, wherein the first protection layer has a thickness of 0.2 to 100 nm.

6. The photovoltaic device according to claim 2, wherein the semiconductor structure assembly further comprises:
a front surface and a rear surface arranged opposite to the front surface, wherein the front surface is textured, and the first protection layer extends to overlay an edge of the front surface and an edge of the rear surface;
wherein the photovoltaic device further comprises:
an anti-reflection layer formed on the front surface and extended to overlay the first protection layer on the edge of the front surface;
a positive electrode formed on the anti-reflection layer and forming an ohmic contact with the front surface;
at least one bus-bar electrode formed on the rear surface ; and
a rear electrode formed on the rear surface to overlay a region on the rear surface without covering the at least one bus-bar electrode.

7. The photovoltaic device according to claim 2, wherein the semiconductor structure assembly further comprises:
a front surface and a rear surface arranged opposite to the front surface, wherein the front surface is textured, and the first protection layer extends to overlay the front surface and an edge of the rear surface;
wherein the photovoltaic device further comprises:
an anti-reflection layer formed to overlay the first protection layer on the front surface;
a positive electrode formed on the anti-reflection layer and forming an ohmic contact with the front surface;
at least one bus-bar electrode formed on the rear surface ; and
a rear electrode formed on the rear surface to overlay a region of the rear surface without covering the at least one bus-bar electrode.

8. The photovoltaic device according to claim 2, wherein the semiconductor structure assembly further comprises a front surface and a rear surface arranged opposite to the front surface;
wherein the front surface is textured, and the first protection layer extends to overlay an edge of the front surface and the rear surface, wherein the photovoltaic device further comprises:
an anti-reflection layer formed on the front surface and extended to overlay the first protection layer on the edge of the front surface;
a positive electrode formed on the anti-reflection layer and forming an ohmic contact with the front surface;
at least one bus-bar electrode formed on the first protection layer and forming an ohmic contact with the rear surface; and
a rear electrode formed to overlay the first protection layer without covering the at least one bus-bar electrode.

9. The photovoltaic device according to claim 2, wherein the semiconductor structure assembly further comprises a front surface and a rear surface arranged opposite to the front surface;
wherein the front surface is textured, the first protection layer extends to overlay the front surface and the rear surface, wherein the photovoltaic device further comprises:
an anti-reflection layer formed to overlay the first protection layer on the front surface;
a positive electrode formed on the anti-reflection layer and forming an ohmic contact with the front surface;
at least one bus-bar electrode formed on the first protection layer and forming an ohmic contact with the rear surface; and
a rear electrode formed to overlay the first protection without covering the at least one bus-bar electrode.

10. A method of manufacturing a photovoltaic device, comprising the following steps:
preparing a semiconductor structure assembly, wherein the semiconductor structure assembly has a plurality of side surfaces, and includes a junction, the junction being a p-n junction, n-p junction, p-i-n junction, n-i-p junction, double junction, or a multiple junction; and
forming a first protection layer to overlay the side surfaces, so as to inhibit occurrence of potential-induced degradation effect within the photovoltaic device.

11. The method of manufacturing a photovoltaic device according to claim 10, wherein the first protection layer is selected from the group consisting of aluminum oxide, titanic oxide, zirconium oxide, hafnium oxide, and a combination thereof.

12. The method of manufacturing a photovoltaic device according to claim 11, further comprising the following step of: forming a second protection layer to overlay the first protection layer.

13. The method of manufacturing a photovoltaic device according to claim 12, wherein the second protection layer is selected from the group consisting of silicon nitride, silicon oxynitride, and a combination thereof.

14. The method of manufacturing a photovoltaic device according to claim 11, wherein the first protection layer has a thickness of 0.2 to 100 nm.

15. The method of manufacturing a photovoltaic device according to claim 11, wherein the semiconductor structure assembly further comprises a front surface and a rear surface arranged opposite to the front surface;
wherein the method further comprises the following steps:
texturing the front surface ;
extending the first protection layer to overlay an edge of the front surface and an edge of the rear surface;
forming an anti-reflection layer on the front surface and extending the anti-reflection layer to overlay the first protection layer on the edge of the front surface;
forming a positive electrode on the anti-reflection layer, wherein the positive electrode forms an ohmic contact with the front surface;
forming at least one rear bus-bar electrode on the rear surface; and
forming a rear electrode on the rear surface to overlay a region on the rear surface without covering the at least one rear bus-bar electrode.

16. The method of manufacturing a photovoltaic device according to claim 11, wherein the semiconductor structure assembly further comprises the following steps:
texturing the front surface;
extending the first protection layer to overlay the front surface and an edge of the rear surface;
forming an anti-reflection layer to overlay the first protection layer on the front surface;
forming a positive electrode on the anti-reflection layer, wherein the positive electrode forms an ohmic contact with the front surface;
forming at least one rear bus-bar electrode on the rear surface; and
forming a rear electrode on the rear surface to overlay a region on the rear surface without covering the at least one rear bus-bar electrode.

17. The method of manufacturing a photovoltaic device according to claim 11, wherein the semiconductor structure assembly comprises a front surface and a rear surface arranged opposite to the front surface;
wherein the method further comprises the following steps:
texturing the front surface ;
extending the first protection layer to overlay an edge of the front surface and the rear surface;
forming an anti-reflection layer on the front surface and extending the anti-reflection layer to overlay the first protection layer on the edge of the front surface;
forming a positive electrode on the anti-reflection layer, wherein the positive electrode forms an ohmic contact with the front surface;
forming at least one rear bus-bar electrode on the first protection layer, wherein the at least one rear bus-bar electrode forms an ohmic contact with the rear surface; and
forming a rear electrode to overlay the first protection without covering the at least one rear bus-bar electrode.

18. The method of manufacturing a photovoltaic device according to claim 11, wherein the semiconductor structure assembly comprises the following steps:
texturing the front surface;
extending the first protection layer to overlay the front surface and the rear surface;
forming an anti-reflection layer to overlay the first protection layer on the front surface;
forming a positive electrode on the anti-reflection layer, wherein the positive electrode forms an ohmic contact with the front surface;
forming at least one rear bus-bar electrode on the first protection layer, wherein the at least one rear bus-bar electrode forms an ohmic contact with the rear surface; and
forming a rear electrode to overlay the first protection layer and without covering the at least on rear bus-bar electrode.
